(19) United States
(12) Patent Application Publication
(10) Pub. No.: US 2025/0384198 A1
(43) Pub. Date: Dec. 18, 2025

(54) LOAD-ADAPTIVE CIRCUIT KNITTING IN QUANTUM COMPUTING ENABLED CLOUD ENVIRONMENTS

(71) Applicant: INTERNATIONAL BUSINESS MACHINES CORPORATION, ARMONK, NY (US)

(72) Inventors: Ritajit Majumdar, Kolkata (IN); Anupama Ray, Bangalore (IN); Padmanabha Venkatagiri Seshadri, Mysore (IN)

(21) Appl. No.: 18/746,096

(22) Filed: Jun. 18, 2024

(51) Int. Cl. G06F 30/392; G06N 10/60

(52) U.S. Cl. CPC G06F 30/392; G06N 10/60

(57) ABSTRACT

In an approach to improve usage efficiency in quantum machines embodiments determine a plurality of cut strategies for a quantum algorithm and determine a plurality of usable qubit groups of a quantum system. Additionally, embodiments cut the quantum algorithm based on each portion of a cut algorithm being computable on a portion of the plurality usable qubit groups. Further, embodiments, apply a portion of the cut algorithm to the portion of the plurality of usable qubit groups.

### BACKGROUND OF THE INVENTION

The present invention relates generally to a method, system, and computer program product for using quantum computing systems. More particularly, the present invention relates to a method, system, and computer program product for maximizing the utilization of a quantum cloud platform.

A quantum processing unit (QPU) is the hardware in which quantum computations are performed. The QPU includes qubits arranged to form a quantum architecture which enable the qubits to interact with each other based on quantum phenomena like entanglement, superposition, and interference. In order to convert logical circuits into operations that can be performed on a QPU, supporting infrastructure may.

Circuit knitting techniques enable the partitioning of large quantum circuits into subcircuits that fit on QPUs and incorporate classical simulations to “knit” together the results to achieve a target answer. The cost is a simulation overhead that scales exponentially in the number of knitted gates. More generally, circuit knitting is the process of decomposing a quantum circuit into smaller circuits, executing those smaller circuits on a quantum processor(s), and then knitting their results into a reconstruction of the original circuit's outcome.

### SUMMARY

Embodiments of the present invention disclose a computer-implemented method, a computer program product, and a system, the computer-implemented method comprising: determining a plurality of cut strategies for a quantum algorithm; determining a plurality of usable qubit groups of a quantum system; cutting the quantum algorithm based on each portion of a cut algorithm being computable on a portion of the plurality usable qubit groups; and applying a portion of the cut algorithm to the portion of the plurality of usable qubit groups.

### BRIEF DESCRIPTION OF THE DRAWINGS

FIG. 1 is a functional block diagram illustrating a distributed data processing environment, executing a QPU cloud utilization efficiency program, in accordance with an embodiment of the present invention;

FIG. 2A is a functional block diagram illustrating a distributed data processing environment, executing a QPU cloud utilization efficiency program, in accordance with an embodiment of the present invention;

FIG. 2B is a functional block diagram illustrating a distributed data processing environment, executing a QPU cloud utilization efficiency program, in accordance with an embodiment of the present invention;

FIG. 3 illustrates operational steps of the QPU cloud utilization efficiency program, on a server computer within the distributed data processing environment of FIGS. 1, in accordance with an embodiment of the present invention; and

FIG. 4 illustrates operational steps of the QPU cloud utilization efficiency program, on a server computer within the distributed data processing environment of FIGS. 1, in accordance with an embodiment of the present invention.

### DETAILED DESCRIPTION

Embodiments recognize that quantum hardware is currently limited and that access to the hardware is expensive and involves long queuing times. Circuit sizes and numbers could vary across jobs causing variations in how many qubits are used at a time. Embodiments recognize that once a job is committed to the queue, there are no dynamics involved in the current approach to adapt to changing a load on the same or other machines. Thus, there is an unfulfilled need to leverage workload splitting techniques to piggy-back on existing jobs to leverage unutilized qubits per job. Further, embodiments encompass more than just equally partitioning the controlled NOT (CNOT) gates by cutting the quantum algorithm based on each portion of the cut algorithm being computable on a portion of the plurality of usable qubit group. Piggy backing is used in the context of communication where data packets are bunched together to be transmitted. Piggy backing, herein, refers to batch sub-circuits of a given quantum job with existing quantum jobs in queue.

Embodiments improve the operation of the quantum system and solve at least the issues stated above by (i) determining a plurality of cut strategies for a quantum algorithm, (ii) determining a plurality of usable qubit groups of a quantum system, (iii) cutting the quantum algorithm based on each portion of the cut algorithm being computable on a portion of the plurality of usable qubit groups, and (iv) applying the portions of the cut algorithm to the portion of the plurality of usable qubit groups. Embodiments result in more efficient usage in machines (e.g., less idling qubits) which results in more efficiency (e.g., higher throughput), which enables an increase in computation while utilizing less energy.

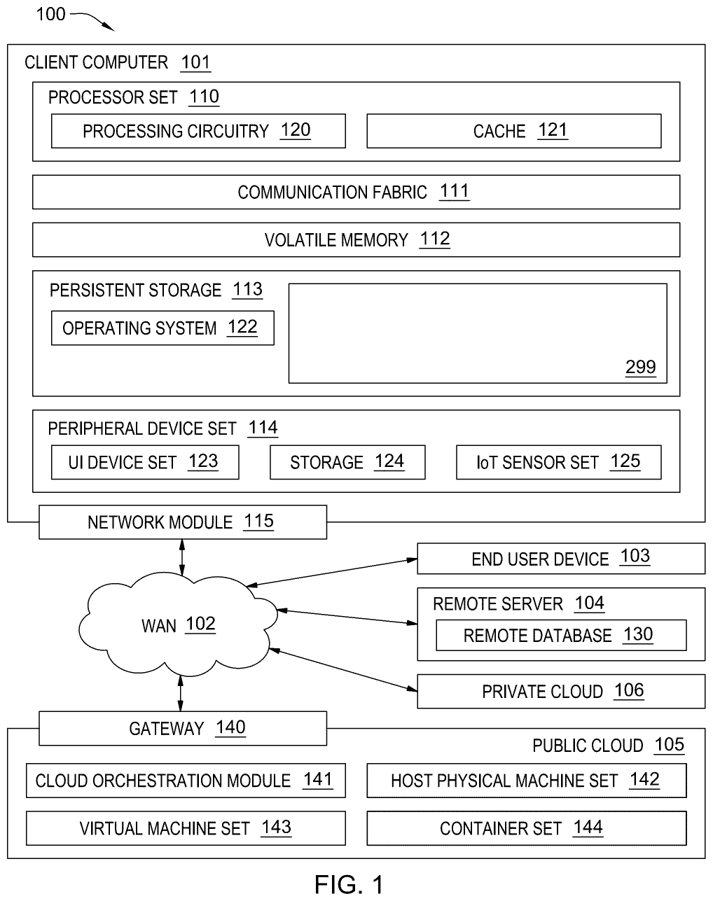

Implementation of embodiments of the invention may take a variety of forms, and exemplary implementation details are discussed subsequently with reference to the Figures (i.e., FIG. 1-FIG. 4).

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as QPU cloud utilization efficiency program (component) 299. In addition to component 299, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and component 299, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in component 299 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in component 299 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economics of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Embodiments improve the art and solve at least the problems stated above by leveraging workload splitting techniques to maximize the utilization of a quantum cloud platform. In various embodiments, component 299 leverages workload splitting techniques to maximize the utilization of a quantum cloud platform by (i) identifying useable qubits across multiple quantum processing units (QPUs) and an enqueued job population, (ii) generating a shard circuit by sharding an enqueued quantum circuit (through the computation of a circuit-cut strategy), wherein the shard circuit refers to one or more sub-circuits that are created after circuit cutting is performed, (iii) utilizing the usable qubits to compute a piggy-back allocation for the shard circuit from the enqueued job, and (iv) performing an assignment of the shard to machines by balancing the trade-off between a noise profile of the machine and a need for reduced execution time. In various embodiments, component 299 improves the operation of the quantum system and solves at least the issues stated above by (i) determining a plurality of cut strategies for a quantum algorithm, (ii) determining a plurality of usable qubit groups of a quantum system, (iii) cutting the quantum algorithm based on each portion of the cut algorithm being computable on a portion of the plurality usable qubit groups, and (iv) applying the portions of the cut algorithm to the portion of the plurality of usable qubit groups. Further, component 299 improves the operation of the quantum system by increasing the usage efficiency in the machines, which results in more efficiency (e.g., higher throughput), which enables an increase in computation while utilizing less energy. Usable qubits are qubits in a quantum system/machine that are unassigned to a job or qubits that are not being utilized during an assigned job (e.g., a 40 qubit machine only using 10 qubit to perform a job comprises 30 usable qubits). Additionally, component 299 improves the art and solves at least the particular problem stated above by not limiting the partitioning of qubits to be of equal size (e.g., gate and wire cutting may not be equal/the same).

In various embodiments, component 299, improves the art and solves at least the particular problems stated above, by maximizing the utilization of a quantum cloud platform with multiple heterogenous QPUs by sharding an enqueued quantum circuit so as to piggy-back the shard circuits (i.e., sub-circuits) with other enqueued jobs that under-utilize the capacity of their assigned QPUs. In various embodiments, the maximization of the utilization a quantum cloud platform with multiple heterogenous QPUs is achieved by using a three-step method: (i) identifying useable qubits across multiple QPUs (e.g., machines) and an enqueued job population, (ii) utilizing the identified useable qubits to compute a piggy-back allocation for one or more shard circuits from an enqueued job without affecting the quality of service for jobs receiving the piggy-backed circuits, wherein the job(s) receiving the piggy-backed circuits are placed in any position in the queue based on an identified cost imposed on the queue, and (iii) performing an assignment of the shard circuits to machines by balancing the trade-off between the noise profile of the machines and the need for reduced execution time (by reducing swap gate requirement). In various embodiments, component 299 may place the job(s) receiving the piggy-backed circuits are placed in a slot in the queue where it is the least burdensome on the queue and/or quantum system, wherein least burdensome occurs when a predetermined threshold is met.

In various embodiments, component 299 identifies useable qubits across multiple QPUs and an enqueued job population. In various embodiments, component 299 receives or retrieves the platform state of the multiple QPUs. The platform state may comprise, but is not limited to, the probability of job failure, list of jobs in the queue, queue lengths, machine capacity, and job resource-footprint. Component 299 may identify the usable qubits by computing the usable qubits across one or more QPUs based on the received or retrieved platform states of the multiple QPUs and generate a histogram of the usable qubits. In various embodiments, the platform states of each of the multiple QPUs (e.g., machines) is received as an input and the histogram is generated and output. Component 299 may utilize the histogram to identify the usable qubits across one or more machines.

In various embodiments, component 299 computes a circuit-cut strategy based on the identified usable qubits. In various embodiments, component 299 weighs pre-identified trade-offs of the allocation of a job across multiple machines when determining a circuit-cut strategy.

In some embodiments, the pre-identified trade-offs comprise, but are not limited to, probability of failure within a predetermined range, usable qubit utilization, and an increase, beyond a predetermined threshold, in classical post-processing. In various embodiments, component 299 utilizes the histogram of usable qubits and Equation 1 to compute a circuit-cut strategy. The histogram of usable qubits enables component 299 to allocate shard circuits on one or more devices. Each cut strategy c∈C which cuts circuits into q_{c} yields a machine set i∈M each with Sᵢ slots which could be usable qubits ≥q_{c} where C is the set of all cut strategies within a given cut budget. In Equation 1, shown below,

$${min}_{c}$$

represents choice c of cut with q_{c} qubits, and

$${\sum }_{i ∈ M} {\sum }_{j ∈ {S}_{i}} E [ {W}_{i , j} ] * \frac{B * {f}_{i , j}}{( 1 + B \times {f}_{i , j} )} + T ( {f}_{i , j} \times {x}_{i , j} )$$

represents the expected completion time for f_{i,j} fraction of capacity x_{i,j} on slot j machine i where

$$E [ {W}_{i , j} ] * \frac{B * {f}_{i , j}}{( 1 + B \times {f}_{i , j} )}$$

represents the weighted waiting time impact and T(f_{i,j}×x_{i,j} represent execution time of the sub-circuit slot. Additionally,

$$( E [ {W}_{m , r} ] * \frac{B * {f}_{m , r}}{( 1 + B \times {f}_{m , r} )} + T ( {f}_{m , r} \times {x}_{m , r} ) )$$

represents the expected completion time for remaining c f_{m,r} fraction of capacity x_{m,r} on original slot r machine m. In various embodiments, Equation 1 is computed such that, Σ_{i|M}Σ_{j∈S}_{ᵢ}f_{i,j}×x_{i,j}=n_{c}×q_{c}. In various embodiments Equation 1 is a linear-fractional objective function and could be converted into a linear objective function and solved.

$${min}_{c} \{ ( {\sum }_{i ∈ M} {\sum }_{j ∈ {S}_{i}} E [ {W}_{i , j} ] * \frac{B * {f}_{i , j}}{( 1 + B \times {f}_{i , j} )} + T ( {f}_{i , j} \times {x}_{i , j} ) ) + ( E [ {W}_{m , r} ] * \frac{B * {f}_{m , r}}{( 1 + B \times {f}_{m , r} )} + T ( {f}_{m , r} \times {x}_{m , r} ) ) \} \qquad Equation 1$$

In various embodiments, using Equation 1, component 299 computes a circuit-cut strategy based on the identified usable qubits. Component 299 may input “cut budget” (B) into Equation 1, which dictates the maximum number of cuts (combining wire and gate cutting) allowed based on the based on a sampling overhead, which may place an upper bound on the classical post-processing time. The sampling overhead is representative of the result of the circuit cuts that require re-processing. When circuit cutting is performed an “n” number of sub-circuits is created and the sampling overhead is a representation of those sub-circuit instances, wherein “n” is any positive integer. Component 299 may sort a list of available hardware based on queuing delays associated with the list of available hardware. In various embodiments, component 299 sorts the available hardware according to queuing delays associated with the available hardware, and stack the available hardware. The list of available hardware may be predetermined and/or identified by component 299. In various embodiments, component 299 may determine if a circuit needs to be cut. In various embodiments, for hardware in a stack, if a single hardware can accommodate the circuit, then there is no need to cut and the job is run on the hardware that has a minimum (i.e., low) queuing delay, wherein a minimum/low queueing delay is a predetermined threshold. However, if the hardware is identified as not being able to accommodate the circuit then component 299 removes at least the top two available hardware systems form the list. For example, if n1, n2, . . . , nk are the available usable qubits among all the hardware, then the circuit is cut (using Equation 1) to fit the subcircuits within these qubits, while minimizing the number of cuts, wherein n1 . . . , nk is the number of available qubits in the hardware (e.g., quantum system).

In various embodiments, if the second hardware can accommodate the circuit, then there is no need to cut the circuit and the job is run on the second hardware. However, if the second hardware can accommodate the circuit, then component 299 will compute a circuit-cut strategy and cut the circuit. For example, if n1, n2 are the number of qubits of the two hardware systems, then component 299 will compute and identify gate and wire cutting strategies which can divide the circuit into n1, n2 subcircuits. If the sizes of both these partitions are greater than the cut budget (B), the 1st hardware is removed and the second hardware is pushed into the stack or component 299 chooses the cutting strategy with the lower number of cuts and executes the subcircuits on the hardware accordingly.

In various embodiments, component 299 utilizes the cut strategy to produce a shard circuit that does not increase or minimizes the queueing delay while simultaneously leveraging the parallelism from the usable qubits. Component 299 may produce a shard circuit by sharding an enqueued quantum circuit. Further, component 299 may utilize the usable qubits to compute a piggy-back allocation for the shard circuit from the enqueued job. Additionally, component 299 may perform an assignment of the shard to machines by balancing the trade-off between a noise profile of the machine and a need for reduced execution time. In various embodiments, component 299 identifies the placement of circuit fragments on usable qubits, places the circuit fragment on the portion of usable qubits and executes the job on the placed circuit. Component 299 may place the shard circuit on a portion of the usable qubits, where the of number of swap gates and noise are minimized. Utilizing the paragraphs above, component 299 may convert the logical circuit to an architecture. Component 299 may convert the logical circuit to an architecture by (i) determining a plurality of cut strategies for a quantum algorithm, (ii) determining a plurality of usable qubit groups of a quantum system, (iii) cutting the quantum algorithm based on each portion of the cut algorithm being computable on a portion of the plurality usable qubit groups, and (iv) applying the portions of the cut algorithm to the portion of the plurality of usable qubit groups.

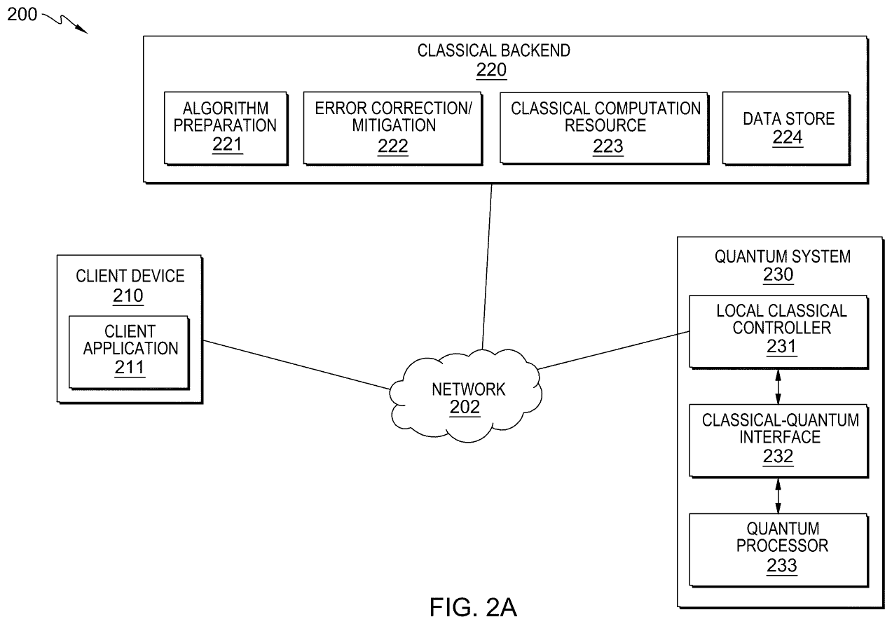

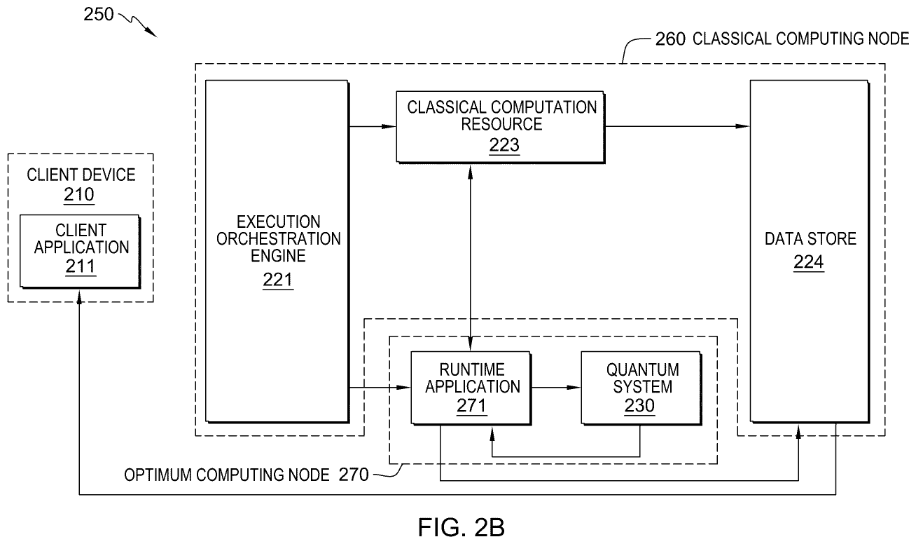

FIG. 2A illustrates a block diagram of an example hybrid computing system 200 that can facilitate execution of a quantum algorithm. As shown, a client device 210 may interface with a classical backend 220 to enable computations with the aid of a quantum system 230.

Network 202 may be any combination of connections and protocols that will support communications between the client device 210, the classical backend 220, and the quantum system 230. In an example embodiment, network 202 may WAN 102.

Client device 210 may be an implementation of computer 101 or EUD 103, described in more detail with reference to FIG. 1, configured to operate in a hybrid computing system 200.

Client application 211 may include an application or program code that includes computations requiring a quantum algorithm or quantum operation. In an embodiment, client application 211 may include an object-oriented programming language, such as Python® (“Python” is a registered trademark of the Python Software Foundation), capable of using programming libraries or modules containing quantum computing commands or algorithms, such as QISKIT (“QISKIT” is a registered trademark of the International Business Machines Corporation). In another embodiment, client application 211 may include machine level instructions for performing a quantum circuit, such as OpenQASM. Additionally, user application may be any other high-level interface, such as a graphical user interface, having the underlying object oriented and/or machine level code as described above.

The classical backend 220 may be an implementation of computer 101, described in more detail with reference to FIG. 1, having program modules configured to operate in a hybrid computing system 200. Such program modules for classical backend 220 may include algorithm preparation 221, classical computation resource 223, and data store 224.

Algorithm preparation 221 may be a program or module capable of preparing algorithms contained in client application 211 for operation on quantum system 230. Algorithm preparation 221 may be instantiated as part of a larger algorithm, such as a function call of an API, or by parsing a hybrid classical-quantum computation into aspects for quantum and classical calculation. Algorithm preparation 221 may additionally compile or transpile quantum circuits that were contained in client application 211 into an assembly language code for use by the local classical controller 231 to enable the quantum processor 233 to perform the logical operations of the circuit on physical structures. During transipilation/compilation an executable quantum circuit in the quantum assembly language may be created based on the calculations to be performed, the data to be analyzed, and the available quantum hardware. In one example embodiment, algorithm preparation 221 may select a quantum circuit from a library of circuits that have been designed for use in a particular problem. In another example embodiment, algorithm preparation 221 may receive a quantum circuit from the client application 211 and may perform transformations on the quantum circuit to make the circuit more efficient, or to fit the quantum circuit to available architecture of the quantum processor 233. Additionally, algorithm preparation 221 may prepare classical data from data store 224, or client application 211, as part of the assembly language code for implementing the quantum circuit by the local classical controller 231. Algorithm preparation 221 may additionally set the number of shots (i.e., one complete execution of a quantum circuit) for each circuit to achieve a robust result of the operation of the algorithm. Further, algorithm preparation 221 may update, or re-compile/re-transiple, the assembly language code based on parallel operations occurring in classical computing resource 223 or results received during execution of the quantum calculation on quantum system 230. Additionally, algorithm preparation 221 may determine the criterion for convergence of the quantum algorithm or hybrid algorithm.

Error Suppression/Mitigation 222 may be a program or module capable of performing error suppression or mitigation techniques for improving the reliability of results of quantum computations. Error suppression is the most basic level of error handling. Error suppression refers to techniques where knowledge about the undesirable effects of quantum hardware is used to introduce customization that can anticipate and avoid the potential impacts of those effects, such as modifying signals from Classical-quantum interface 232 based on the undesirable effects. Error mitigation uses the outputs of ensembles of circuits to reduce or eliminate the effect of noise in estimating expectation values. Error mitigation may include techniques such as Zero Noise Extrapolation (ZNE) and Probabilistic Error Correction (PEC).

Classical computing resource 223 may be a program or module capable of performing classical (e.g., binary, digital) calculations contained in client application 211. Classical calculations may include formal logical decisions, AI/ML algorithms, floating point operations, and/or simulation of Quantum operations.

Data store 224 may be a repository for data to be analyzed using a quantum computing algorithm, as well as the results of such analysis. Data store 224 may be an implementation of storage 124 and/or remote database 130, described in more detail with reference to FIG. 1, configured to operate in a hybrid computing system 200.

The quantum system 230 can be any suitable set of components capable of performing quantum operations on a physical system. In the example embodiment depicted in FIG. 2, quantum system 230 includes a local classical controller 231, a classical-quantum interface 232, and quantum processor 233. In some embodiments, all or part of each of the local classical controller 231, a classical-quantum interface 232, and quantum processor 233 may be located in a cryogenic environment to aid in the performance of the quantum operations. In an embodiment, classical backend 220 and quantum system 230 may be co-located to reduce the communication latency between the devices.

Local classical controller 231 may be any combination of classical computing components capable of aiding a quantum computation, such as executing a one or more quantum operations to form a quantum circuit, by providing commands to a classical-quantum interface 232 as to the type and order of signals to provide to the quantum processor 233. Local classical controller 231 may additionally perform other low/no latency functions, such as error correction, to enable efficient quantum computations. Such digital computing devices may include processors and memory for storing and executing quantum commands using classical-quantum interface 232. Additionally, such digital computing devices may include devices having communication protocols for receiving such commands and sending results of the performed quantum computations to classical backend 220. Additionally, the digital computing devices may include communications interfaces with the classical-quantum interface 232. In an embodiment, local classical controller 231 may include all components of computer 101, or alternatively may be individual components configured for specific quantum computing functionality, such as processor set 110, communication fabric 111, volatile memory 112, persistent storage 113, and network module 115.

Classical-quantum interface 232 may be any combination of devices capable of receiving command signals from local classical controller 231 and converting those signals into a format for performing quantum operations on the quantum processor 233. Such signals may include electrical (e.g., RF, microwave, DC), optical signals, magnetic signals, or vibrational signals to perform one or more single qubit operations (e.g., Pauli gate, Hadamard gate, Phase gate, Identity gate), signals to preform multi-qubit operations (e.g., CNOT-gate, CZ-gate, SWAP gate, Toffoli gate), qubit state readout signals, and any other signals that might enable quantum calculations, quantum error correction, and initiate the readout of a state of a qubit. Additionally, classical-quantum interface 232 may be capable of converting signals received from the quantum processor 233 into digital signals capable of processing and transmitting by local classical controller 231 and classical backend 220. Such signals may include qubit state readouts. Devices included in classical-quantum interface 232 may include, but are not limited to, digital-to-analog converters, analog-to-digital converters, waveform generators, attenuators, amplifiers, filters, optical fibers, and lasers.

Quantum processor 233 may be any hardware capable of using quantum states to process information. Such hardware may include a collection of qubits, mechanisms to couple/entangle the qubits, and any required signal routings to communicate between qubits or with classical-quantum interface 232 in order to process information using the quantum states. Such qubits may include, but are not limited to, charge qubits, flux qubits, phase qubits, spin qubits, and trapped ion qubits, or any other suitable qubit structures. The architecture of quantum processor 233, such as the arrangement of data qubits, error correcting qubits, and the couplings amongst them, may be a consideration in performing a quantum circuit on quantum processor 233.

Referring now to FIG. 2B, a block diagram is depicted showing an example architecture, and data transmission, of hybrid computation system 250 employed using a cloud architecture for classical backend 220. Hybrid computation system 250 receives an algorithm containing a computation from a client application 211 of client device 210. Upon receipt of the algorithm and request from client application 211, hybrid computation system 250 instantiates a classical computing node 260 and a quantum computing node 270 to manage the parallel computations. The classical computing node 260 may include one or more classical computers capable of working in tandem (e.g., utilizing the cloud computing environment described with reference to FIGS. Y and Y+1). For example, classical computing node 260 may include an execution orchestration engine 261, one or more classical computation resources 223, and a result data store 224. The backend quantum runtime system (e.g., network 202) may include a combination of classical and quantum computing components acting together to perform quantum calculations on quantum hardware including, for example, one or more quantum systems 230. The quantum computing node 270 may include a quantum runtime application 271 and one or more quantum systems 230.

The client application 211 may include programing instructions to perform quantum and classical calculations. In an embodiment, client application 211 may be in a general purpose computing language, such as an object oriented computing language (e.g., Python®), that may include classical and quantum functions and function calls. This may enable developers to operate in environments they are comfortable with, thereby enabling a lower barrier of adoption for quantum computation.

The execution orchestration engine 261, in using algorithm preparation 221, may parse the client application 211 into a quantum logic/operations portion for implementation on a quantum computing node 270, and a classical logic/operations portion for implementation on a classical node 260 using a classical computation resource 223. In an embodiment, parsing the client application 211 may include performing one or more data processing steps prior to operating the quantum logic using the processed data. In an embodiment, parsing the client application 211 may including segmenting a quantum circuit into portions that are capable of being processed by quantum computing node 270, in which the partial results of each of the segmented quantum circuits may be recombined as a result to the quantum circuit. Execution orchestration engine 261 may parse the hybrid algorithm such that a portion of the algorithm is performed using classical computation resources 223 and a session of quantum computing node 270 may open to perform a portion of the algorithm. Quantum runtime application 271 may communicate, directly or indirectly, with classical computation resources 223 by sending parameters/information between the session to perform parallel calculations and generate/update instructions of quantum assembly language to operate quantum system 230 and receiving parameters/information/results from the session on the quantum system 230. Following the parsing of the hybrid algorithm for calculation on quantum computing node 270 and classical computing node 260, the parallel nodes may iterate the session to convergence by passing the results of quantum circuits, or partial quantum circuits, performed on quantum system 230 to classical computing resource 223 for further calculations. Additionally, runtime application 271, using algorithm preparation 221, may re-parse aspects of the hybrid algorithm to improve convergence or accuracy of the result. Such operation results, and progress of convergence, may be sent back to client device 210 as the operations are being performed. By operating execution orchestration engine 261 in a cloud environment, the environment may scale (e.g., use additional computers to perform operations necessary) as required by the client application 211 without any input from the creators/implementors of client application 211. Additionally, execution orchestration engine 261, while parsing the client application 211 into classical and quantum operations, may generate parameters, function calls, or other mechanisms in which classical computation resource 223 and quantum computing node 270 may pass information (e.g., data, commands) between the components such that the performance of the computations enabled by client application 211 is efficient.

Classical computation resources 223 may perform classical computations (e.g., formal logical decisions, AI/ML algorithms, floating point operations, simulation of Quantum operations) that aid/enable/parallelize the computations instructed by client application 211. By utilizing classical computation resources 223 in an adaptively scalable environment, such as a cloud environment, the environment may scale (e.g., use additional computers to perform operations necessary including adding more classical computation resources 223, additional quantum systems 230, and/or additional resources of quantum systems 230 within a given quantum computing node 270) as required by the client application 211 without any input from the creators/implementors/developers of client application 211, and may appear seamless to any individual implementing client application 211 as there are no required programming instructions in client application 211 needed to adapt to the classical computation resources 223. Thus, for example, such scaling of quantum computing resources and classical computing resources may be provided as needed without user intervention. Scaling may reduce the idle time, and thus reduce capacity and management of computers in classical computing node 260.

Result data store 224 may store, and return to client device 210, states, configuration data, etc., as well as the results of the computations of the client application 211.

Implementation of the systems described herein may enable hybrid computing system 200, through the use of quantum system 230, to process information, or solve problems, in a manner not previously capable. The efficient parsing of the quantum or hybrid algorithm into classical and quantum segments for calculation may achieve efficient and accurate quantum calculations from the quantum system 230 for problems that are exponentially difficult to perform using classical backend 220. Additionally, the quantum assembly language created by classical backend 220 may enable quantum system 230 to use quantum states to perform calculations that are not classically efficient or accurate. Specifically, increasing the usage efficiency in the machines, which results in more efficiency (e.g., higher throughput) by leveraging workload splitting techniques to maximize the utilization of a quantum cloud platform, which enables an increase in computation while utilizing less energy. Such improvement may reduce the classical resources required to perform the calculation of the quantum or hybrid algorithm, by improving the capabilities of the quantum system 230.

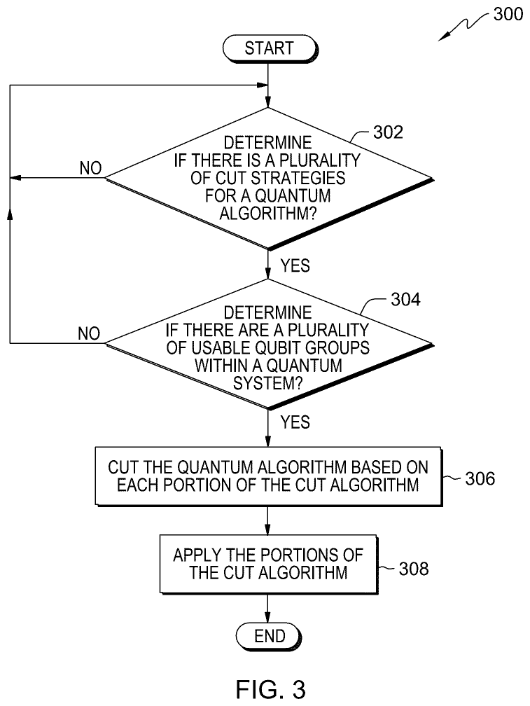

FIG. 3 illustrates operational steps of component 299, generally designated 300, in communication with client computer 101, remote server 104, private cloud 106, EUD 103, public cloud 105, quantum system 230, classical backend 220, and/or hybrid computation system 250, within distributed data processing environment 100, for optimizing the efficiency of job execution and QPU cloud utilization in a quantum system, in accordance with an embodiment of the present invention. FIG. 3 provides an illustration of one implementation and does not imply any limitations with regard to the environments in which different embodiments may be implemented. Many modifications to the depicted environment may be made by those skilled in the art without departing from the scope of the invention as recited by the claims.

In block 302, component 299 determines a plurality of cut strategies for a quantum algorithm. In various embodiments, component 299 computes a circuit-cut strategy based on the identified usable qubits in one or more quantum machines (machines). In various embodiments, component 299 weighs pre-identified trade-offs of the allocation of a job across multiple machines when determining a circuit-cut strategy. In various embodiments, component 299 utilizes the histogram of usable qubits and Equation I to compute a circuit-cut strategy. In the depicted embodiment, if component 299 determines that there is a plurality of cut strategies for a quantum algorithm (Yes block) then component 299 advances to block 304. However, in the depicted embodiment if component 299 determines that there are no cut strategies for a quantum algorithm (No block) then component 299 re-executes block 302. In various embodiments, using Equation 1, component 299 computes a circuit-cut strategy based on the identified usable qubits. Component 299 may input a “cut budget” into Equation 1, which dictates the maximum number of cuts (combining wire and gate cutting) allowed based on the based on the sampling overhead, which may place an upper bound on the classical postprocessing time. Component 299 may sort a list of available hardware based on queuing delays associated with the list of available hardware. In various embodiments, component 299 sorts the available hardware according to queuing delays associated with the available hardware, and stack the available hardware. The list of available hardware may be predetermined and/or identified by component 299. In various embodiments, component 299 may determine if a circuit needs to be cut. In various embodiments, for hardware in the stack, if a single hardware can accommodate the circuit, then there is no need to cut and the job is run on the hardware that has a minimum (i.e., low) queuing delay, wherein a minimum/low queueing delay is a predetermined threshold.

However, if the hardware is identified as not being able to accommodate the circuit then component 299 pops at least the top two available hardware. For example, if n1, n2, . . . , nk are the available usable qubits among all the hardware, then the circuit is cut (using Equation 1) to fit the subcircuits within these qubits, while minimizing the number of cuts, wherein n1 . . . , nk is the number of available qubits in the hardware (e.g., quantum system). In various embodiments, if the second hardware can accommodate the circuit, then there is no need to cut the circuit and the job is run on the second hardware. However, if the second hardware can accommodate the circuit, then component 299 will compute a circuit-cut strategy and cut the circuit. For example, if n1, n2 are the number of qubits of the two hardware systems, then component 299 will compute and identify gate and wire cutting strategies which can divide the circuit into n1, n2 subcircuits. If the sizes of both these partitions are greater than the cut buget (B), the 1st hardware is removed and the second hardware is pushed into the stack or component 299 chooses the cutting strategy with the lower number of cuts and executes the subcircuits on the hardware accordingly.

In block 304, component 299 determines a plurality of usable qubit of usable qubit groups of a quantum system. In various embodiments, component 299 identifies useable qubits across multiple QPUs and an enqueued job population. Component 299 may determine where to place the plurality of cut strategies based on the number of swap gates and noise. In the depicted embodiment, if component 299 determines that there is a plurality of usable qubits within the group of quantum systems (Yes block) then component 299 advances to block 306. However, in the depicted embodiment if component 299 determines that there are no usable qubits within the group of quantum systems (No block) then component 299 re-executes block 302. In various embodiments, component 299 identifies useable qubits across multiple QPUs and an enqueued job population. In various embodiments, component 299 receives or retrieves the platform state of the multiple QPUs. The platform state may comprise, but is not limited to, the probability of job failure, list of jobs in the queue, queue lengths, machine capacity, and job resource-footprint. Component 299 may identify the usable qubits by computing the usable qubits across one or more QPUs based on the received or retrieved platform states of the multiple QPUs and generate a histogram of the usable qubits. In various embodiments, the platform states of each of the multiple QPUs (e.g., machines) is received as an input and the histogram is generated and output. Component 299 may utilize the histogram to identify the usable qubits across one or more machines.

In block 306, component 299 cuts the quantum algorithm based on each portion of the cut algorithm. In various embodiments, component 299 may utilize the cut strategy to produce a shard circuit that does not increase or minimizes the queueing delay while simultaneously leveraging the parallelism from the usable qubits. Component 299 may produce a shard circuit by sharding an enqueued quantum circuit. In various embodiments, component 299 utilizes the cut strategy to produce a shard circuit that does not increase or minimizes the queueing delay while simultaneously leveraging the parallelism from the usable qubits. Component 299 may produce a shard circuit by sharding an enqueued quantum circuit. Further, component 299 may utilize the usable qubits to compute a piggy-back allocation for the shard circuit from the enqueued job.

In block 308, component 299 applies the portions of the cut algorithm. In various embodiments, component 299 may utilize the usable qubits to compute a piggy-back allocation for the shard circuit from the enqueued job. Additionally, component 299 may perform an assignment of the shard to machines by balancing the trade-off between a noise profile of the machine and a need for reduced execution time. For example, there are two devices m1 and m2 with queues q1 and q2 with noise profile n1 and noise profile n2 respectively, wherein n1 is greater than n2 and q1 is greater than q2. Here, the trade-off will be between choosing m1 with least amount of jobs in the queue or m2 with lesser noise. Component 299 may balance the trade-off based on identified or received predetermined parameters and/or user preferences.

Component 299 may perform an assignment of the shard to machines by balancing the trade-off between a noise profile of the machine and a need for reduced execution time. In various embodiments, component 299 identifies the placement of circuit fragments on usable qubits, places the circuit fragment on the portion of usable qubits and executes the job on the placed circuit. Component 299 may place the shard circuit on a portion of the usable qubits, where the of number of swap gates and noise are minimized.

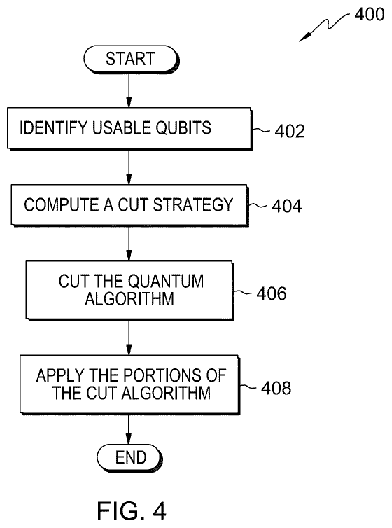

FIG. 4 illustrates operational steps of component 299, generally designated 400, in communication with client computer 101, remote server 104, private cloud 106, EUD 103, public cloud 105, quantum system 230, classical backend 220, and/or hybrid computation system 250, within distributed data processing environment 100, for optimizing the efficiency of job execution and QPU cloud utilization in a quantum system, in accordance with an embodiment of the present invention. FIG. 4 provides an illustration of one implementation and does not imply any limitations with regard to the environments in which different embodiments may be implemented. Many modifications to the depicted environment may be made by those skilled in the art without departing from the scope of the invention as recited by the claims.

In block 402, component 299 identifies usable qubits. In various embodiments, component 299 identifies useable qubits across multiple QPUs and an enqueued job population. In various embodiments, component 299 receives or retrieves the platform state of the multiple QPUs. The platform state may comprise, but is not limited to, the probability of job failure, list of jobs in the queue, queue lengths, machine capacity, and job resource-footprint. Component 299 may identify the usable qubits by computing the usable qubits across one or more QPUs based on the received or retrieved platform states of the multiple QPUs and generate a histogram of the usable qubits. In various embodiments, the platform states of each of the multiple QPUs (e.g., machines) is received as an input and the histogram is generated and output. Component 299 may utilize the histogram to identify the usable qubits across one or more machines.

In block 404, component 299 computes a cut strategy. In various embodiments, component 299 computes a circuit-cut strategy based on the identified usable qubits. In various embodiments, component 299 weighs pre-identified trade-offs of the allocation of a job across multiple machines when determining a circuit-cut strategy. In some embodiments, the pre-identified trade-offs comprise, but are not limited to, probability of failure within a predetermined range, usable qubit utilization, and an increase, beyond a predetermined threshold, in classical post-processing. In various embodiments, component 299 utilizes the histogram of usable qubits and Equation 1 to compute a circuit-cut strategy.

In block 406, component 299 cuts the quantum algorithm. In various embodiments, component 299 utilizes the cut strategy to produce a shard circuit that does not increase or minimizes the queueing delay while simultaneously leveraging the parallelism from the usable qubits. Component 299 may produce a shard circuit by sharding an enqueued quantum circuit. Further, component 299 may utilize the usable qubits to compute a piggy-back allocation for the shard circuit from the enqueued job.

In block 408, component 299 applies the portions of the cut algorithm. Additionally, component 299 may perform an assignment of the shard to machines by balancing the trade-off between a noise profile of the machine and a need for reduced execution time. In various embodiments, component 299 identifies the placement of circuit fragments on usable qubits, places the circuit fragment on the portion of usable qubits and executes the job on the placed circuit. Component 299 may place the shard circuit on a portion of the usable qubits, where the of number of swap gates and noise are minimized. The minimization of the of number of swap gates and noise are minimized is determined based on the balancing of predetermined parameters. In various embodiments, component 299 utilizes the placed circuit fragments across the usable qubits to efficiently execute a job.

The programs described herein are identified based upon the application for which they are implemented in a specific embodiment of the invention. However, it should be appreciated that any particular program nomenclature herein is used merely for convenience, and thus the invention should not be limited to use solely in any specific application identified and/or implied by such nomenclature.

The present invention may be a system, a method, and/or a computer program product. The computer program product may include a computer readable storage medium (or media) having computer readable program instructions thereon for causing a processor to carry out aspects of the present invention.

Computer readable program instructions described herein may be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, may be implemented by computer readable program instructions.

These computer readable program instructions may be provided to a processor of a general-purpose computer, a special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that may direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus, or other device to produce a computer implemented process, such that the instructions which execute on the computer, other programmable apparatus, or other device implement the functions/acts specified in the flowchart and/or block diagram block or blocks.

The flowchart and block diagrams in the Figures (i.e., FIG.) illustrate the architecture, functionality, and operation of possible implementations of systems, methods, and computer program products according to various embodiments of the present invention. In this regard, each block in the flowchart or block diagrams may represent a module, a segment, or a portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, may be implemented by special purpose hardware-based systems that perform the specified functions or acts or carry out combinations of special purpose hardware and computer instructions.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A computer-implemented method comprising:
determining a plurality of cut strategies for a quantum algorithm;
determining a plurality of usable qubit groups of a quantum system;
cutting the quantum algorithm based on each portion of a cut algorithm being computable on a portion of the plurality usable qubit groups; and
applying a portion of the cut algorithm to the portion of the plurality of usable qubit groups.

2. The computer-implemented method of claim 1, further comprising:
identifying useable qubits across one or more quantum machines and an enqueued job population.

3. The computer-implemented method of claim 2, further comprising:
producing a sub-circuit by sharding an enqueued quantum circuit; and
utilizing the plurality of usable qubit groups to compute a piggy-back allocation for the sub-circuit from the enqueued job.

4. The computer-implemented method of claim 3, further comprising:
performing an assignment of the sub-circuit by balancing a trade-off between a noise profile of the quantum system and a need for reduced execution time.

5. The computer-implemented method of claim 2, further comprising:
identifying a placement for a sub-circuit on the plurality of usable qubit groups;
placing the sub-circuit on the portion of the plurality of usable qubit groups; and
executing the job on the placed sub-circuit.

6. The computer-implemented method of claim 1, wherein determining the plurality of cut strategies comprises:
computing a circuit-cut strategy based on the plurality of usable qubit groups across one or more quantum machines, wherein pre-identified trade-offs of an allocation of a job across multiple quantum machines are weighed when determining the circuit-cut strategy.

7. The computer-implemented method of claim 6, wherein the pre-identified trade-offs comprise: probability of failure within a predetermined range, usable qubit utilization, and an increase, beyond a predetermined threshold, in classical post-processing.

8. A computer system comprising:
one or more computer processors;
one or more computer readable storage devices;
program instructions to determine a plurality of cut strategies for a quantum algorithm;
program instructions to determine a plurality of usable qubit groups of a quantum system;
program instructions to cut the quantum algorithm based on each portion of a cut algorithm being computable on a portion of the plurality usable qubit groups; and
program instructions to apply a portion of the cut algorithm to the portion of the plurality of usable qubit groups.

9. The computer system of claim 8, further comprising:
program instructions to identify useable qubits across one or more quantum machines and an enqueued job population.

10. The computer system of claim 9, further comprising:
program instructions to produce a sub-circuit by sharding an enqueued quantum circuit; and
program instructions to utilize the plurality of usable qubit groups to compute a piggy-back allocation for the sub-circuit from the enqueued job.

11. The computer system of claim 10, further comprising:
program instructions to perform an assignment of the sub-circuit by balancing a trade-off between a noise profile of the quantum system and a need for reduced execution time.

12. The computer system of claim 9, further comprising:
program instructions to identify a placement for a sub-circuit on the plurality of usable qubit groups;
program instructions to place the sub-circuit on the portion of the plurality of usable qubit groups; and
program instructions to execute the job on the placed sub-circuit.

13. The computer system of claim 8, wherein determining the plurality of cut strategies comprises:
program instructions to compute a circuit-cut strategy based on the plurality of usable qubit groups across one or more quantum machines, wherein pre-identified trade-offs of an allocation of a job across multiple quantum machines are weighed when determining the circuit-cut strategy.

14. The computer system of claim 13, wherein the pre-identified trade-offs comprise:
probability of failure within a predetermined range, usable qubit utilization, and an increase, beyond a predetermined threshold, in classical post-processing.

15. A computer program product comprising:
one or more computer readable storage devices and program instructions stored on the one or more computer readable storage devices, the stored program instructions comprising:
program instructions to determine a plurality of cut strategies for a quantum algorithm;
program instructions to determine a plurality of usable qubit groups of a quantum system;
program instructions to cut the quantum algorithm based on each portion of a cut algorithm being computable on a portion of the plurality usable qubit groups; and
program instructions to apply a portion of the cut algorithm to the portion of the plurality of usable qubit groups.

16. The computer program product of claim 15, further comprising:
program instructions to identify useable qubits across one or more quantum machines and an enqueued job population.

17. The computer program product of claim 16, further comprising:
program instructions to produce a sub-circuit by sharding an enqueued quantum circuit; and
program instructions to utilize the plurality of usable qubit groups to compute a piggy-back allocation for the sub-circuit from the enqueued job.

18. The computer program product of claim 17, further comprising:
program instructions to perform an assignment of the sub-circuit by balancing a trade-off between a noise profile of the quantum system and a need for reduced execution time.

19. The computer program product of claim 16, further comprising:
program instructions to identify a placement for a sub-circuit on the plurality of usable qubit groups;
program instructions to place the sub-circuit on the portion of the plurality of usable qubit groups; and
program instructions to execute the job on the placed sub-circuit.

20. The computer program product of claim 15, wherein determining the plurality of cut strategies comprises:
program instructions to compute a circuit-cut strategy based on the plurality of usable qubit groups across one or more quantum machines, wherein pre-identified trade-offs of an allocation of a job across multiple quantum machines are weighed when determining the circuit-cut strategy, wherein the pre-identified trade-offs comprise: probability of failure within a predetermined range, usable qubit utilization, and an increase, beyond a predetermined threshold. in classical post-processing.
